(19) United States
(12) Patent Application Publication
(10) Pub. No.: US 2015/0221669 A1
(43) Pub. Date: Aug. 6, 2015

(54) Thin FilmTransistor, Array Substrate, And Manufacturing Method Thereof

(71) Applicant: BOE TECHNOLOGY GROUP CO., LTD., Chaoyang District, Beijing (CN)

(72) Inventor: Shuang Sun, Beijing (CN)

(73) Assignee: BOE Technology Group Co., Ltd., Chaoyang District, Beijing (CN)

(21) Appl. No.: 13/995,105

(22) PCT Filed: Dec. 10, 2012
(86) PCT No.: PCT/CN2012/086306

§ 371 Date: Jun. 17, 2013

(30) Foreign Application Priority Data
Jun. 8, 2012 (CN) 201210189705.3

(51) Int. Cl. H01L 27/12; H01L 21/306; H01L 21/768; H01L 29/786; H01L 29/417

(52) U.S. Cl. CPC H01L 27/124; H01L 27/1288; H01L 29/78696; H01L 29/41733; H01L 21/76802; H01L 21/76877; H01L 21/30604

(57) ABSTRACT

A thin film transistor, an array substrate (1) and a manufacturing method thereof are provided. The thin film transistor comprises a substrate (1) and a gate electrode (2), a gate insulating layer (3), a semiconductor layer (4), a protective layer (5), an ohmic contact layer (6), a source electrode (7) and a drain electrode (8) successively stacked on the substrate (1), wherein the protective layer (5) has two via holes (11) over the semiconductor layer (4) so as to expose the underlying semiconductor layer (4), the semiconductor layer (4) exposed by the via hole (11) is covered by the ohmic contact layer (6); the source and drain electrodes (7, 8) are connected to the semiconductor layer (4) through the ohmic contact layer (6) at the via hole (11).

### FIELD OF THE INVENTION

Embodiments of the present invention relate to a thin film transistor, an array substrate and a manufacturing method thereof.

### BACKGROUND OF THE INVENTION

Thin film transistor liquid crystal display (TFT-LCD) has attracted much attention because of its properties such as small size, low power consumption, being free of radiation, occupies a leading position in the field of flat panel display, and is widely applied to various fields. As for a TFT-LCD, a manufacturing process of an array substrate determines the performance, yield and cost of the products. In order to effectively reduce the manufacturing cost and improve the yield of the TFT-LCD, the manufacturing method of the array substrate has experienced a development from a seven-mask process at the beginning to a four-mask process using a gray mask technology.

In a method of manufacturing the array substrate of the TFT-LCD by the four-mask process in the prior art, the step for forming a channel of the thin film transistor (TFT) comprises: etching off a metal layer at the channel by a dry or wet etch method, then etching off an ohmic contact layer at the channel by a wet etch method. In order to ensure that the ohmic contact layer at the channel is completely removed, over-etching is generally required, i.e., etching a portion of the semiconductor layer, and thus the semiconductor layer is generally made be relatively thick. However, the thick semiconductor layer will make the off-state current of the TFT be increased, thereby affecting the switching characteristics of the TFT.

### SUMMARY OF THE INVENTION

An embodiment of the invention provides a thin film transistor comprising a substrate and a gate electrode, a gate insulating layer, a semiconductor layer, a protective layer, an ohmic contact layer, a source electrode and a drain electrode successively stacked on the substrate, wherein the protective layer has two via holes over the semiconductor layer so as to expose the underlying semiconductor layer, the semiconductor layer exposed by the via hole is covered by the ohmic contact layer; the source and drain electrodes are connected to the semiconductor layer through the ohmic contact layer at the via hole.

In one example, the gate electrode, the gate insulating layer and the semiconductor layer are of a same shape.

In one example, the source electrode and the drain electrode have a same shape as that of the ohmic contact layer.

In one example, the ohmic contact layer is formed by a doped semiconductor film.

In one example, the semiconductor layer has a thickness of 400 Å to 155 Å.

Another embodiment of the invention provides an array substrate comprising the thin film transistor according to any of claims 1 to 5, wherein it further comprises a passivation layer, a pixel electrode, a gate line and a data line, the pixel electrode is connected to the drain electrode, the gate line is connected to the gate electrode, and the data line is connected to the source electrode.

In one example, the passivation layer overlays the thin film transistor, and the pixel electrode is located in a region not covered by the passivation layer.

Still another embodiment of the invention provides a manufacturing method of an array substrate, comprising the steps of: S1, forming patterns including a gate line, a gate electrode, a gate insulating layer and a semiconductor layer on a substrate; S2, forming a pattern of a protective layer, the protective layer having two via holes formed therein at locations opposed to the semiconductor layer so as to expose the semiconductor layer; S3, forming patterns including an ohmic contact layer, a data line, a source electrode, and a drain electrode, wherein the ohmic contact layer is formed on at least the semiconductor layer exposed by the via holes, the source and drain electrodes are connected to the semiconductor layer through the ohmic contact layer at the via holes; S4, forming a pattern of a passivation layer, wherein the passivation layer has a gate line interface via hole and a data line interface via hole provided therein; and S5, forming a pattern of a pixel electrode.

In one example, the step S1 comprises: S101, forming a gate metal film, a gate insulating layer film and a semiconductor film successively on the substrate; S102, forming photoresist on the semiconductor film; S103, exposing and developing by using a gray mask or a half-tone mask, so that the photoresist in a region of a gate electrode is completely retained, the photoresist in a region of a gate line is partially retained, and remaining portion of the photoresist is completely removed; and SI04, forming patterns including the gate line, the gate electrode, a gate insulating layer and a semiconductor layer through multi-step etching, and removing the remaining photoresist.

In one example, the step S2 comprises: S201, forming a protective layer film on the substrate after the step S1; S202, forming photoresist on the protective layer film; S203, exposing and developing by using a normal masking process, so that the photoresist at via holes to be formed in the protective layer film is completely removed, remaining portion of the photoresist is completely retained; and S204, etching off the protective layer film in the region where the photoresist is completely removed by a dry etch method, so as to form protective layer via holes, and removing the remaining photoresist.

In one example, the step S3 comprises: S301, forming a doped semiconductor film and a source-drain metal film continuously on the substrate after the step S2; S302, forming photoresist on the source-drain metal film; S303, exposing and developing by using a normal masking process, so that the photoresist in a region including a data line, a source electrode and a drain electrode is completely retained, and remaining portion of the photoresist is completely removed; and S304, etching off the source-drain metal film and the doped semiconductor film in the region where the photoresist is completely removed by a dry etch method so as to form patterns including an ohmic contact layer, the data line, the source electrode, and the drain electrode, and removing the remaining photoresist.

In one example, wherein the step S4 comprises: S401, forming a passivation layer film on the substrate after the step S3; S402, forming photoresist on the passivation layer film; S403, exposing and developing by using a normal masking process, so that the photoresist in a region including a gate line interface via hole, a data line interface via hole and a pixel electrode is completely removed, and remaining portion of the photoresist is completely retained; and S404, etching off the passivation layer film in the region where the photoresist is completely removed by a dry etch method so as to from a pattern of a passivation layer, the gate line interface via hole and a data line interface via hole being provided in the passivation layer.

In one example, the step S5 comprises: forming a transparent conductive film on the substrate after the step 5404, lifting off the photoresist so that the transparent conductive film thereon is removed together, so as to form a pattern of a pixel electrode.

The above technical solution has the following advantages: In the thin film transistor of the present invention, the source electrode and the drain electrode are connected to the ohmic contact layer and the semiconductor layer through the via holes in the protective layer, and the ohmic contact layer at positions needs to be over-etched has the protective layer thereunder, thus the semiconductor layer will not be affected upon over-etching the ohmic contact layer at the channel region, so that the thickness of the semiconductor layer in the manufacturing process can be reduced, and the switching characteristics of the thin film transistor is improved. As for the array substrate using the above transistor, it will also have the above advantages.

### BRIEF DESCRIPTION OF THE DRAWINGS

In order to clearly illustrate the technical solutions of the embodiments of the invention, the drawings of the embodiments will be briefly described in the following; it is obvious that the described drawings are only related to some embodiments of the invention and thus are not limitative of the invention.

FIG. 1 is a schematic diagram of a structure after a first masking process according to an embodiment of the invention;

FIG. 2a is a schematic diagram after depositing a gate metal film, a gate insulating layer thin film and a semiconductor film in the first masking process according to the embodiment of the invention;

FIG. 2b is a schematic diagram after exposing and developing in the first masking process according to the embodiment of the invention;

FIG. 2c is a schematic diagram after etching in the first masking process according to the embodiment of the invention;

FIG. 3 is a schematic diagram of a structure after a second masking process according to the embodiment of the invention;

FIG. 4a is a schematic diagram after depositing a protective layer film in the second masking process according to the embodiment of the invention;

FIG. 4b is a schematic diagram after exposing and developing in the second masking process according to the embodiment of the invention;

FIG. 4c is a schematic diagram after etching in the second masking process according to the embodiment of the invention;

FIG. 5 is a schematic diagram of a structure after a third masking process according to the embodiment of the invention;

FIG. 6a is a schematic diagram after depositing a doped semiconductor film and a source-drain metal film in the third masking process according to the embodiment of the invention;

FIG. 6b is a schematic diagram after exposing and developing in the third masking process according to the embodiment of the invention;

FIG. 6c is a schematic diagram after etching in the third masking process according to the embodiment of the invention;

FIG. 7 is a schematic diagram of a structure after a fourth masking process according to the embodiment of the invention.

FIG. 8a is a schematic diagram after depositing a passivation layer film in the fourth masking process according to the embodiment of the invention;

FIG. 8b is a schematic diagram after exposing and developing in the fourth masking process according to the embodiment of the invention;

FIG. 8c is a schematic diagram after etching in the fourth masking process according to the embodiment of the invention; and

FIG. 8d is a schematic diagram after depositing a transparent conductive film in the fourth masking process according to the embodiment of the invention.

### DETAILED DESCRIPTION OF THE PREFERRED EMBODIMENTS

In order to make objects, technical details and advantages of the embodiments of the invention apparent, the technical solutions of the embodiments will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

### First Embodiment

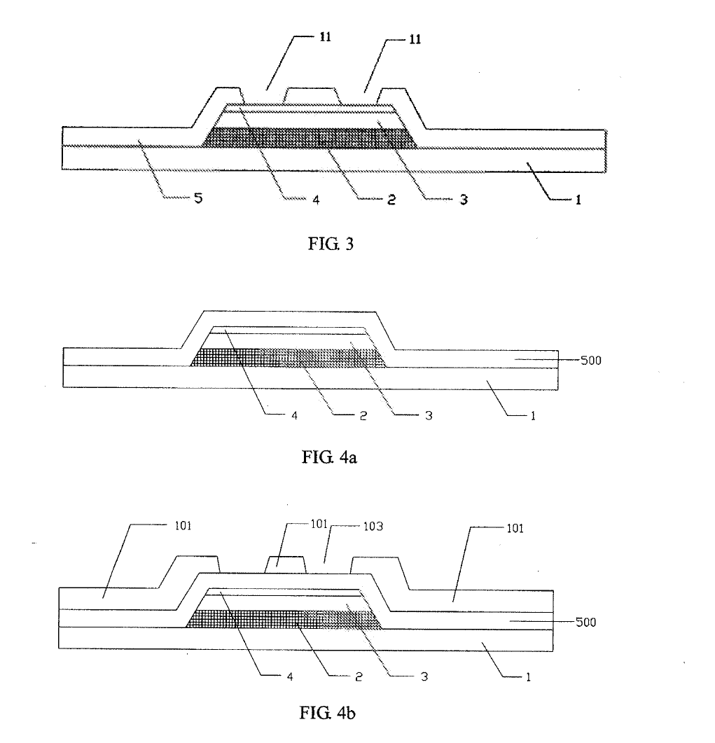

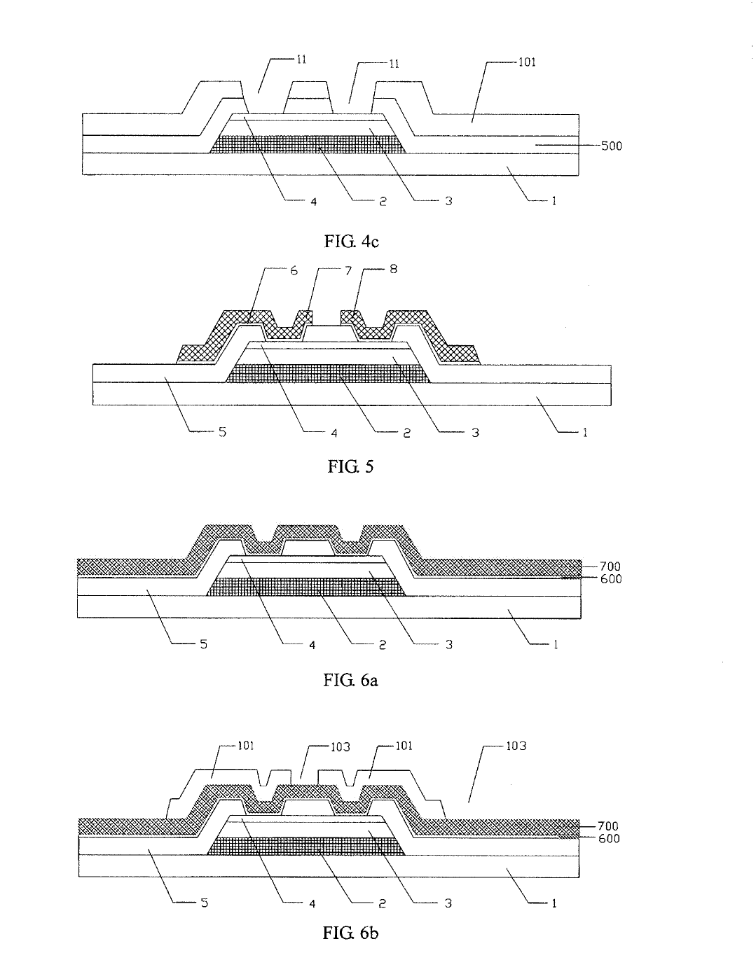

The present embodiment provides a thin film transistor, and its structure is illustrated in FIG. 5. A gate electrode 2, a gate insulating layer 3, a semiconductor layer 4, a protective layer 5, an ohmic contact layer 6, a source electrode 7 and a drain electrode 8 are successively stacked on a substrate 1 (such as a glass substrate or a plastic substrate, etc.). The protective layer 5 has two via holes 11 therein over the semiconductor layer 4 (as illustrated in FIG. 3), and an ohmic contact layer 6 is formed on the semiconductor layer 4 at the via holes 11 by a doped semiconductor; the source electrode 7 and the drain electrode 8 are connected to the semiconductor layer 4 through the ohmic contact layer 6 at the via holes 11.

For example, the ohmic contact layer 6 may be formed of a doped semiconductor film. For example, the semiconductor layer 4 may have a thickness of 400 Å˜1500 Å.

Preferably, as illustrated in FIG. 5, the gate electrode 2, the gate insulating layer 3 and the semiconductor layer 4 have a same shape. In this case, the gate electrode 2, the gate insulating layer 3 and the semiconductor layer 4 may be formed in one patterning process (masking process), which facilitates to save the processing time and processing cost. Of course, the shapes of the gate electrode, the gate insulating layer and the semiconductor layer can be inconsistent with each other; in this case, multiple patterning processes may be required.

Preferably, the source electrode 7 and the drain electrode 8 have the same shape as that of the ohmic contact layer 6. In this case, the source electrode 7, the drain electrode 8 and the ohmic contact layer 6 may be formed in one patterning process (masking process), which facilitates to save the processing time and processing cost. Of course, the shape of the source electrode 7 and the drain electrode 8 and the shape of the ohmic contact layer 6 can also be inconsistent with each other; in this case, multiple patterning processes may be required.

### Second Embodiment

The present embodiment provides an array substrate, comprising the thin film transistor as described in the first embodiment. In addition to the thin film transistor, it further comprises a passivation layer, a pixel electrode, a gate line and a data line, and the pixel electrode is connected to the drain electrode of the thin film transistor, the gate line is connected to the gate electrode of the thin film transistor, and the data line is connected to the source electrode of the thin film transistor.

Specifically, the array substrate provided by the present embodiment is illustrated in FIG. 7. A gate electrode 2, a gate insulating layer 3, a semiconductor layer 4, a protective layer 5, an ohmic contact layer 6, a source electrode 7, a drain electrode 8, a passivation layer 9 and a pixel electrode 10 are successively stacked on a substrate 1 (such as a glass substrate or a plastic substrate, etc.). The protective layer 5 has two via holes 11 therein over the semiconductor layer 4 (as illustrated in FIG. 3), and the ohmic contact layer 6 is formed on the semiconductor layer 4 at the via holes 11 by a doped semiconductor; the source electrode 7 and the drain electrode 8 are connected to the semiconductor layer 4 through the ohmic contact layer 6 at the via holes 11. The pixel electrode 10 is connected to the drain electrode 8.

For example, the passivation layer 9 overlays the thin film transistor, and the pixel electrode 10 is located in a region not covered by the passivation layer 9.

As for the connecting manner between the pixel electrode 10 and the drain electrode 8, the pixel electrode 10 is directly coated on the protective layer and the drain electrode 8 and is connected to the drain electrode 8 (as illustrate in FIG. 7); alternatively, the pixel electrode 10 can be connected to the drain electrode 8 through a via hole in the passivation layer 9; or, the connection can be accomplished in other feasible ways.

The thin film transistor adopted in the present embodiment may be any one described in the first embodiment. For convenience of description, no pattern such as gate line and data line is shown in FIG. 7.

### Third Embodiment

The present embodiment provides a method of manufacturing the array substrate according to the second embodiment, and the specific processing steps are as follows:

S1, forming patterns including a gate line, a gate electrode, a gate insulating layer and a semiconductor layer on a substrate;

S2, forming a pattern of a protective layer, the protective layer having two via holes formed therein at locations opposed to the semiconductor layer so as to expose the semiconductor layer;

S3, forming patterns including an ohmic contact layer, a data line, a source electrode and a drain electrode, wherein the ohmic contact layer is formed on at least the semiconductor layer exposed by the via holes, the source and drain electrodes are connected to the semiconductor layer through the ohmic contact layer at the via holes;

S4, forming a pattern of a passivation layer, wherein the passivation layer has a gate line interface via hole and a data line interface via hole provided therein; and

S5, forming a pattern of a pixel electrode.

In the embodiment of the invention, the steps S1-S5 each can be accomplished by selecting a specific method according to the actual requirements, which are not limited here.

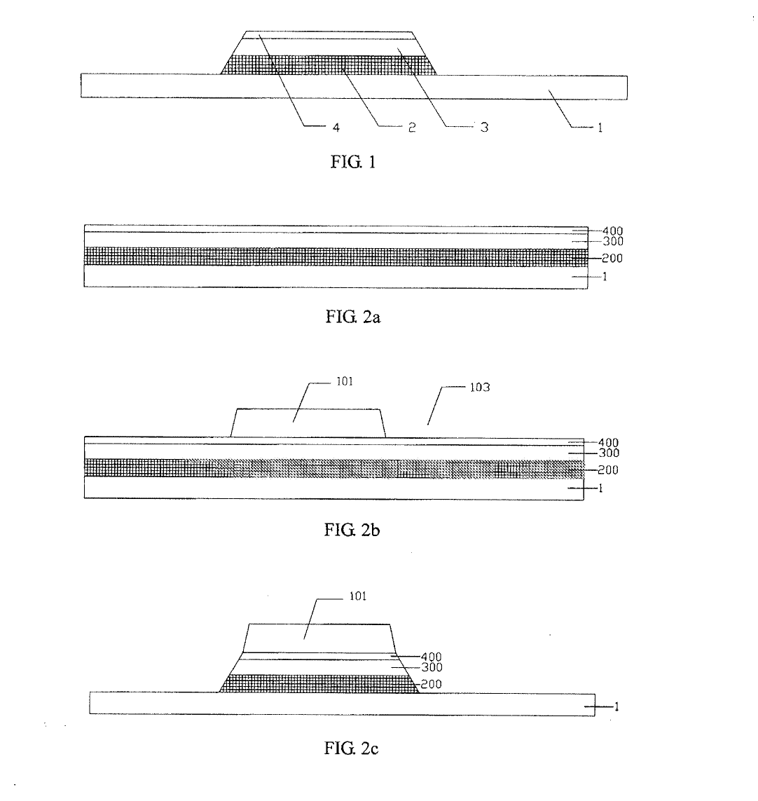

Hereinafter, the above processing steps are described by taking a specific embodiment in which a four-mask process is used to complete the manufacturing process as an example. The array substrate including the thin film transistor according to the above embodiments is manufactured by a four-mask process in the present embodiment, and the specific manufacturing steps are illustrated in FIGS. 1 to 8d.

S1, patterns including a gate line, a gate electrode, a gate insulating layer and a semiconductor layer are formed on a substrate.

FIG. 1 is a schematic diagram of a structure after a first masking process according to an embodiment of the invention. The specific fabricating method is as follows:

S101, a gate metal film, a gate insulating layer film and a semiconductor film are successively formed on the substrate. For example, the specific implementation can be as follows: a gate metal film 200 is deposited on a glass substrate 1 by a magnetron sputtering deposition to a thickness of 1000 <˜7000 Å, and then a gate insulating layer film 300 with a thickness of 1000 Å˜6000Å and a semiconductor film 400 with a thickness of 400 Å˜1500Å are deposited successively by using a plasma enhanced chemical vapor deposition (PECVD) method, as illustrated in FIG. 2a. The gate metal film 200 can employ molybdenum, aluminum, aluminum-nickel alloy, molybdenum-tungsten alloy, chromium, or copper or other metals, and can also employ the combination of the above-described material films; the gate insulating layer thin film 300 may employ silicon nitride, silicon oxide or silicon oxynitride; and the semiconductor film 400 may employ amorphous silicon, etc.

S102, on the glass substrate after the step S101, a layer of photoresist is spin-coated; alternatively the photoresist can be formed by other methods.

S103, the first masking process: the exposure and development are performed by using a half-tone or gray tone mask, so that the photoresist is formed into a photoresist completely retained region 101, a photoresist partially retained region and a photoresist completely removed region 103, the photoresist completely retained region 101 corresponding to the gate region, the photoresist partially retained region corresponding to the region of the gate line (the gate line region and the photoresist partially retained region corresponding thereto are not illustrated in the drawings), and the photoresist completely removed region 103 corresponding to a region outside of the above regions; after the development, the photoresist in the photoresist completely retained region 101 does not change, the photoresist in the photoresist partially retained region is thinned, and the photoresist in the photoresist completely removed region 103 is completely removed, as illustrated in FIG. 2b.

S104, patterns including the gate line, the gate electrode, the gate insulating layer and the semiconductor layer are formed through multi-step etching, and the remaining photoresist is removed. For example, the specific implementation may be as follows, by using a dry etch process, sequentially etching off the semiconductor film 400 and the gate insulating layer film 300 in the photoresist completely removed region 103, and then by using a wet etch process, etching off the exposed gate metal film 200, as illustrated in FIG. 2c. After an ashing process, the photoresist in the photoresist completely retained region 101 is thinned, and the photoresist in the photoresist partially retained region is completely removed, and the semiconductor film 400 and the gate insulating layer film 300 in the photoresist partially retained region is etched off by using a dry etch process sequentially. After removing the photoresist, the patterns including the gate line (not illustrated), the gate electrode 2, the gate insulating layer 3 and the semiconductor layer 4 are formed, as illustrated in FIG. 1.

S2, a pattern of a protective layer is formed, and the protective layer has two via holes formed therein at locations opposed to the semiconductor layer so as to expose the semiconductor layer.

FIG. 3 is a schematic diagram of a structure after a second masking process according to the embodiment of the invention, the specific fabricating method is as follows:

S201, a protective layer film is formed on the substrate after the step SI. For example, the specific implementation can be as follows: a protective layer film is deposited on the substrate after step S104 by using a PEC VD method to a thickness of 1000 Å˜6000 Å film 500, as illustrated in FIG. 4a. The protective layer film 500 may employ silicon nitride, silicon oxide, silicon oxynitride or the like.

S202, a layer of photoresist is formed. For example, a layer of photoresist is spin-coated on the glass substrate after the step S201.

S203, exposure and development are performed by using a normal masking process, so that the photoresist at via holes to be formed in the protective layer film is completely removed, the remaining portion of the photoresist is completely retained. For example, the specific implementation can be as follows: by using a normal masking process, the photoresist is formed into a photoresist completely retained region 101 and a photoresist completely removed region 103, the photoresist completely removed region 103 corresponding to a region of the protective layer via holes, the photoresist completely retained region 101 corresponding to a region outside of the above pattern. After the development treatment, the photoresist in the photoresist completely retained region 101 does not change, and the photoresist in the photoresist completely removed region 103 is completely removed, illustrated in FIG. 4b.

S204, the protective layer film 500 in the region 103 where the photoresist is completely removed is etched off by a dry etch method, as illustrated in FIG. 4c;

After removing the photoresist, the protective layer via holes 11 are formed, as illustrated in FIG. 3.

S3, patterns including an ohmic contact layer, a data line, a source electrode, a drain electrode are formed. The ohmic contact layer is formed on the semiconductor layer at the via holes, and the source and drain electrodes are connected to the ohmic contact layer.

FIG. 5 is a schematic diagram of a structure after a third masking process according to the embodiment of the invention, the specific fabricating method is as follows:

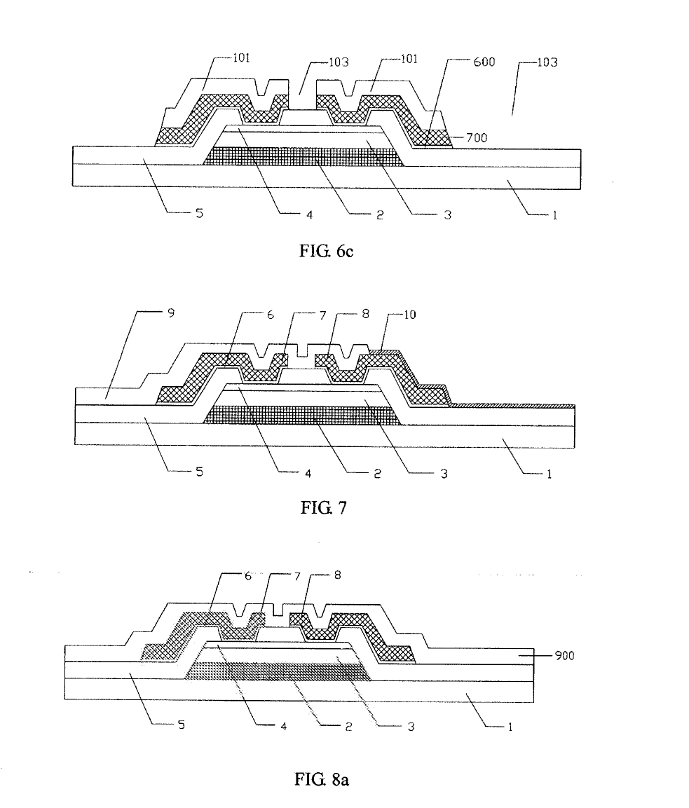

S301, a doped semiconductor film and a source-drain metal film are continuously formed on the substrate after the step S2. For example, the specific implementation can be as follows: a layer of the doped semiconductor film 600 is deposited on the substrate after the step 5204 by using a PECVD method to a thickness of 400 Å˜1000 Å, and then a source-drain metal thin film 700 is deposited by using a magnetron sputtering method to a thickness 1000 Å˜7000 Å, as illustrate in FIG. 6a. The source-drain metal film 700 can employ molybdenum, aluminum, aluminum-nickel alloy, molybdenum-tungsten alloy, chromium, or copper or other metals, or employ a combination of films of several materials as mentioned above.

S302, a layer of photoresist is spin-coated on the glass substrate after the step S301.

S303, exposure and development are performed by using a normal masking process, so that the photoresist in a region including the data line, the source electrode and the drain electrode is completely retained, and the remaining portion of the photoresist is completely removed. For example, the specific implementation can be as follows: by using a normal masking process, the photoresist is formed into a photoresist completely retained region 101 and a photoresist completely removed region 103, the photoresist completely retained region 101 corresponding to a region of the data line, the source electrode and the drain electrode, the photoresist completely removed region 103 corresponding to a region outside of the above patterns. After the development treatment, the photoresist in the photoresist completely retained region 101 does not change, and the photoresist in the photoresist completely removed region 103 is completely removed, illustrated in FIG. 6b.

S304, the source-drain metal film 700 and the doped semiconductor film 600 in the photoresist completely removed region 103 is etched off by using a dry etch process, as illustrated in FIG. 6c.

After removing the photoresist, the ohmic contact layer 6, the data line (not illustrated), the source electrode 7, and the drain electrode 8 are formed, as illustrated in FIG. 5.

S4, a pattern of a passivation layer is formed, and the passivation layer has a gate line interface via hole and a data line interface via hole provided therein.

FIG. 5 is a schematic diagram of a structure after a fourth masking process according to the embodiment of the invention, the specific fabricating method is as follows:

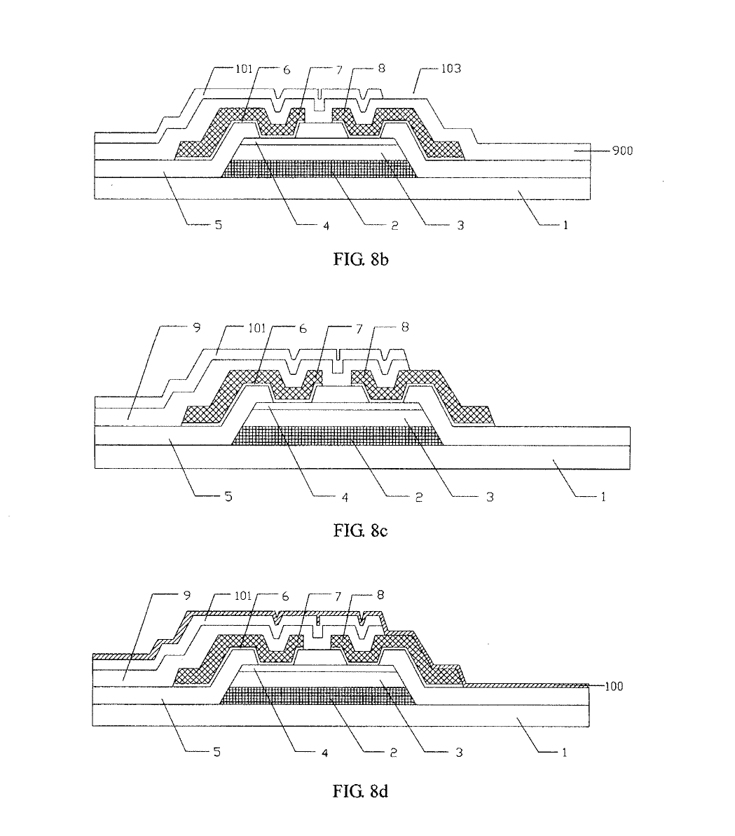

S401, a passivation layer film is formed on the substrate after the step S3. For example, the specific implementation can be as follows: a passivation layer film 900 is deposited on the substrate after the step S304 by using a PECVD method to a thickness of 1000 Å˜6000 Å, as illustrated in FIG. 8a. The passivation layer film 900 may employ silicon nitride, silicon oxide, silicon oxynitride, or the like.

S402, a layer of photoresist is spin-coated on the glass substrate after the step 401.

S403, exposure and development are performed by using a normal masking process, so that the photoresist in a region including the gate line interface via hole and the data line interface via hole is completely removed, and the remaining portion of the photoresist is completely retained. For example, the specific implementation can be as follows: by using a normal masking process, the photoresist is formed into a photoresist completely retained region 101 and a photoresist completely removed region 103, the photoresist completely removed region 103 corresponding to the region of the gate line interface via hole and the data line interface via hole, the photoresist completely retained region 101 corresponding to a region outside of the above patterns. After the development treatment, the photoresist in the photoresist completely retained region 101 does not change, and the photoresist in the photoresist completely removed region 103 is completely removed, as illustrated in FIG. 8b.

S404, the passivation layer film 900 in the photoresist completely removed region 103 is etched off by a dry etch method so as to form a pattern of a passivation layer, as illustrate in FIG. 8c. In the present step, the remaining photoresist is retained.

S5, a pattern of a pixel electrode is formed.

A transparent conductive film 100 is deposited on the substrate after the step S404 by using a magnetron sputtering method to a thickness of 400 Å˜1000 Å, as illustrated in FIG. 8d. The transparent conductive film 100 may employ indium tin oxide (ITO), indium zinc oxide (IZO), aluminum zinc oxide or the like. The photoresist remaining in the step S404 is then lifted off, and the transparent conductive film thereon is removed together, so as to form the pattern of the pixel electrode 10. The pixel electrode 10 is connected to the drain electrode 8.

Thus, the fabrication of the thin-film transistor array substrate according to the above embodiments is completed.

In the embodiment, the steps S101 to S104 employ a grey tone masking process, and the patterns of the gate line, the gate electrode, the gate insulating layer and the semiconductor layer are formed through one masking process. If the production cost is not considered, the patterns of the gate line, the gate electrode, the gate insulating layer and the semiconductor layer can also be sequentially formed by multiple masking processes. Although this will increase the process complexity and increase production cost, the structure of the thin film transistor array substrate according to the present invention can also be fabricated.

In the thin film transistor of the present invention, the source electrode and the drain electrode are connected to the ohmic contact layer and the semiconductor layer through the via holes in the protective layer, and the ohmic contact layer at positions required to be over-etched has the protective layer thereunder, thus the semiconductor layer will not be affected upon over-etching the ohmic contact layer at the channel region, so that the thickness of the semiconductor layer in the manufacturing process can be reduced, and the switching characteristics of the thin film transistor is improved. As for the array substrate using the above transistor or the array substrate manufactured by the manufacturing method according to the invention, it will also have the above advantages.

The above description is only exemplary implementations of the present invention, but not for limiting the scope of the invention; instead, the scope of the invention should be defined by the appended claims.

1. A thin film transistor, comprising a substrate and a gate electrode, a gate insulating layer, a semiconductor layer, a protective layer, an ohmic contact layer, a source electrode and a drain electrode successively stacked on the substrate, wherein the protective layer has two via holes over the semiconductor layer so as to expose the underlying semiconductor layer, the semiconductor layer exposed by the via hole is covered by the ohmic contact layer; the source and drain electrodes are connected to the semiconductor layer through the ohmic contact layer at the via hole.

2. The thin film transistor according to claim 1, wherein the gate electrode, the gate insulating layer and the semiconductor layer are of a same shape.

3. The thin film transistor according to claim 1, wherein the source electrode and the drain electrode have a same shape as that of the ohmic contact layer.

4. The thin film transistor according to claim 1, wherein the ohmic contact layer is formed by a doped semiconductor film.

5. The thin film transistor according to claim 1, wherein the semiconductor layer has a thickness of 400′ to 1500′.

6. An array substrate, comprising the thin film transistor according to claim 1, wherein it further comprises a passivation layer, a pixel electrode, a gate line and a data line, the pixel electrode is connected to the drain electrode, the gate line is connected to the gate electrode, and the data line is connected to the source electrode.

7. The array substrate according to claim 6, wherein the passivation layer overlays the thin film transistor, the pixel electrode is located in a region not covered by the passivation layer.

8. A manufacturing method of an array substrate, comprising the steps of:
S1, forming patterns including a gate line, a gate electrode, a gate insulating layer and a semiconductor layer on a substrate;
S2, forming a pattern of a protective layer, the protective layer having two via holes formed therein at locations opposed to the semiconductor layer so as to expose the semiconductor layer;
S3, forming patterns including an ohmic contact layer, a data line, a source electrode, and a drain electrode, wherein the ohmic contact layer is formed on at least the semiconductor layer exposed by the via holes, the source and drain electrodes are connected to the semiconductor layer through the ohmic contact layer at the via holes;
S4, forming a pattern of a passivation layer, wherein the passivation layer has a gate line interface via hole and a data line interface via hole provided therein; and
S5, forming a pattern of a pixel electrode.

9. The manufacturing method of the array substrate according to claim 8, wherein the step S1 comprises:
S101, forming a gate metal film, a gate insulating layer film and a semiconductor film successively on the substrate;
S102, forming photoresist on the semiconductor film;
S103, exposing and developing by using a gray mask or a half-tone mask, so that the photoresist in a region of a gate electrode is completely retained, the photoresist in a region of a gate line is partially retained, and remaining portion of the photoresist is completely removed; and
S104, forming patterns including the gate line, the gate electrode, a gate insulating layer and a semiconductor layer through multi-step etching, and removing the remaining photoresist.

10. The manufacturing method of the array substrate according to claim 8, wherein the step S2 comprises:
S201, forming a protective layer film on the substrate after the step S1;
S202, forming photoresist on the protective layer film;
S203, exposing and developing by using a normal masking process, so that the photoresist at via holes to be formed in the protective layer film is completely removed, remaining portion of the photoresist is completely retained; and
S204, etching off the protective layer film in the region where the photoresist is completely removed by a dry etch method, so as to form protective layer via holes, and removing the remaining photoresist.

11. The manufacturing method of the array substrate according to claim 8, wherein the step S3 comprises:
S301, forming a doped semiconductor film and a source-drain metal film continuously on the substrate after the step S2;
S302, forming photoresist on the source-drain metal film;
S303, exposing and developing by using a normal masking process, so that the photoresist in a region including a data line, a source electrode and a drain electrode is completely retained, and remaining portion of the photoresist is completely removed; and
S304, etching off the source-drain metal film and the doped semiconductor film in the region where the photoresist is completely removed by a dry etch method so as to form patterns including an ohmic contact layer, the data line, the source electrode, and the drain electrode, and removing the remaining photoresist.

12. The manufacturing method of the array substrate according to claim 8, wherein the step S4 comprises:
S401, forming a passivation layer film on the substrate after the step S3;
S402, forming photoresist on the passivation layer film;
S403, exposing and developing by using a normal masking process, so that the photoresist in a region including a gate line interface via hole, a data line interface via hole and a pixel electrode is completely removed, and remaining portion of the photoresist is completely retained; and
S404, etching off the passivation layer film in the region where the photoresist is completely removed by a dry etch method so as to from a pattern of a passivation layer, the gate line interface via hole and a data line interface via hole being provided in the passivation layer.

13. The manufacturing method of the array substrate according to claim 8, wherein the step S5 comprises:
forming a transparent conductive film on the substrate after the step S404, lifting off the photoresist so that the transparent conductive film thereon is removed together, so as to form a pattern of a pixel electrode.
